(19) United States
(12) Patent Application Publication
(10) Pub. No.: US 2011/0145477 A1
(43) Pub. Date: Jun. 16, 2011

(54) FLASH TRANSLATION LAYER USING PHASE CHANGE MEMORY

(76) Inventor: John C. Rudelic, Folsom, CA (US)

(21) Appl. No.: 12/638,956

(22) Filed: Dec. 15, 2009

(51) Int. Cl. G06F 12/00; G06F 12/02; G11C 11/00; G06F 12/10

(52) U.S. Cl. 711/103; 365/163; 711/206; 711/E12.001; 711/E12.008; 711/E12.058

(57) ABSTRACT

A FLASH translation layer (FTL) includes a translation table that is maintained in non-FLASH memory. The translation table maps logical addresses to physical addresses and may be maintained in phase change memory (PCM). A bad block table (BBT) may also be maintained in non-FLASH memory.

### FIELD

The present invention relates generally to data storage in memory devices, and more specifically to data storage in nonvolatile memory.

### BACKGROUND

FLASH memory is a type of nonvolatile memory. It is “nonvolatile” because it retains its memory contents even when power is lost. Individual locations within FLASH memory typically cannot be overwritten. Instead, entire blocks of data within FLASH memory devices must be erased before individual locations within the block can be written. This is referred to herein as the “block erase characteristic” of FLASH memory.

FLASH memory is in widespread use in systems that benefit from nonvolatile memory. Examples include, but are not limited to, cell phones, cameras, media players, and the like. Logical addresses used by the system may be mapped to physical locations in the FLASH memory of the system. Mapping of logical addresses to physical locations within FLASH memory is complicated because of the block erase characteristics of FLASH memory.

FLASH memory is also in widespread use for disk emulation (also referred to as “solid state disks”). In these systems, read and write requests are presented to the solid state disks as disk operations (e.g., reading of disk sectors and writing of disk sectors). Mapping of disk sectors to physical locations within FLASH memory is complicated because of the block erase characteristics of FLASH memory.

### BRIEF DESCRIPTION OF THE DRAWINGS

Embodiments of the invention are illustrated by way of example and not limitation in the figures of the accompanying drawings, in which:

FIG. 1 shows an electronic system in accordance with various embodiments of the invention;

FIGS. 2 and 3 show memory systems in accordance with various embodiments of the present invention;

FIGS. 4A and 4B show FLASH translation layer (FTL) translation tables and FLASH bad block tables (BBT) maintained in phase change memory (PCM); and

FIGS. 5 and 6 show flow diagrams in accordance with various embodiments of the present invention.

### DESCRIPTION OF EMBODIMENTS

In the following detailed description, reference is made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein in connection with one embodiment may be implemented within other embodiments without departing from the scope of the invention. In addition, it is to be understood that the location or arrangement of individual elements within each disclosed embodiment may be modified without departing from the scope of the invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout the several views.

Some portions of the detailed description that follows are presented in terms of algorithms and symbolic representations of operations on data bits or binary digital signals within a computer memory. These algorithmic descriptions and representations may be the techniques used by those skilled in the data processing arts to convey the substance of their work to others skilled in the art.

An algorithm is here, and generally, considered to be a self-consistent sequence of acts or operations leading to a desired result. These include physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers or the like. It should be understood, however, that all of these and similar terms are to be associated with the appropriate physical quantities and are merely convenient labels applied to these quantities.

Unless specifically stated otherwise, as apparent from the following discussions, it is appreciated that throughout the specification discussions utilizing terms such as “processing,” “computing,” “calculating,” “determining,” or the like, refer to the action and/or processes of a computer or computing system, or similar electronic computing device, that manipulate and/or transform data represented as physical, such as electronic, quantities within the computing system's registers and/or memories into other data similarly represented as physical quantities within the computing system's memories, registers or other such information storage, transmission or display devices.

Embodiments of the present invention may include apparatuses for performing the operations herein. An apparatus may be specially constructed for the desired purposes, or it may comprise a general purpose computing device selectively activated or reconfigured by a program stored in the device. Such a program may be stored on a storage medium, such as, but not limited to, any type of disk including floppy disks, optical disks, compact disc read only memories (CD-ROMs), magnetic-optical disks, read-only memories (ROMs), random access memories (RAMs), nonvolatile memories such as electrically programmable read-only memories (EPROMs), electrically erasable and programmable read only memories (EEPROMs), or FLASH memories, or any other type of media suitable for storing electronic instructions, and capable of being coupled to a system bus for a computing device.

Use of the terms “coupled” and “connected”, along with their derivatives, may be used. It should be understood that these terms are not intended as synonyms for each other. Rather, in particular embodiments, “connected” may be used to indicate that two or more elements are in direct physical or electrical contact with each other. “Coupled” my be used to indicate that two or more elements are in either direct or indirect (with other intervening elements between them) physical or electrical contact with each other, and/or that the two or more elements co-operate or interact with each other (e.g. as in a cause an effect relationship).

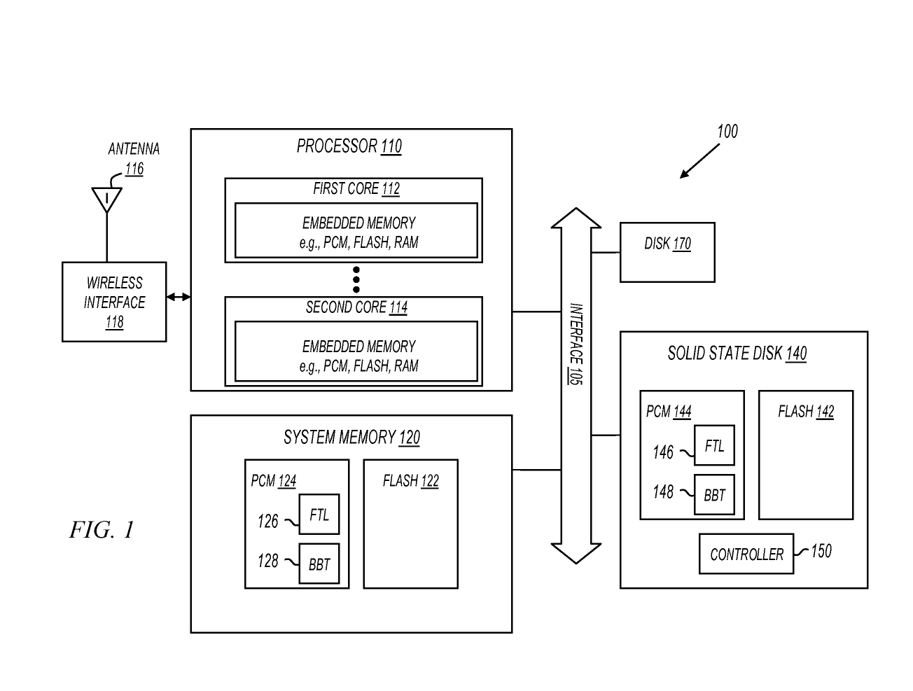

FIG. 1 shows a system 100 in accordance with various embodiments of the present invention. System 100 may be any type of system with memory. For example, system 100 may be a computer or a mobile phone with nonvolatile memory. Also for example, system 100 may be a global positioning system (GPS) receiver or a portable media player with nonvolatile memory. System 100 may be any type of device without departing from the scope of the present invention.

In some embodiments, system 100 has a wireless interface 118. Wireless interface 118 is coupled to antenna 116 to allow system 100 to communicate with other over-the-air communication devices. As such, system 100 may operate as a cellular device or a device that operates in wireless networks such as, for example, Wireless Local Area Networks (WLANs), WiMax and Mobile WiMax based systems, Wideband Code Division Multiple Access (WCDMA), and Global System for Mobile Communications (GSM) networks, any of which may or may not operate in accordance with one or more standards. The various embodiments of the invention are not limited to operate in the above network types; this is simply a list of examples. It should be understood that the scope of the present invention is not limited by the types of, the number of, or the frequency of the communication protocols that may be used by system 100. Embodiments are not, however, limited to wireless communication embodiments. Other non-wireless applications can use the various embodiments of the invention.

In some embodiments, wireless interface 118 may include one or more stand-alone Radio Frequency (RF) discrete or integrated analog circuits, and in other embodiments, wireless interface 118 may be embedded within an integrated circuit that includes other components. For example, in some embodiments, wireless interface 118 may be included on a common integrated circuit with processor 110.

Processor 110 includes at least one core 112, 114, and each core may include memory. For example, first core 112 may include volatile or nonvolatile memory such as PCM, FLASH, or RAM. Each core may include any combination of different types of memory without departing from the scope of the present invention. Processor 110 may execute instructions from any suitable memory within system 100. For example, any memory within a processor core, or any of the memory devices within system memory 120, may be considered a computer-readable medium that has instructions stored that when accessed cause processor 110 to perform embodiments of the invention.

Processor 110 is shown coupled to interface 105. Interface 105 provides communication between processor 110 and the various other devices coupled to interface 105. For example, processor 110 may communicate with memory devices in system memory 120, solid state disk (SSD) 140, as well as disk 170. Interface 105 can include serial and/or parallel buses to share information along with control signal lines to be used to provide handshaking between processor 110 and the various other devices coupled to interface 105.

System 100 may or may not include disk 170. For example, some mobile phone embodiments do not include disk 170. Also for example, some computer embodiments include disk 170.

System memory 120 includes FLASH memory 122 and phase change memory (PCM) 124. FLASH memory stores information by storing charge on a floating gate in a Metal Oxide Semiconductor (MOS) transistor. The stored charge alters the threshold voltage of the transistor, and the difference in threshold voltage is “read” to determine whether the stored information is a “0” or a “1”. In some embodiments varying amounts of charge are stored on the floating gate to represent more than one bit of information per memory cell. This is sometimes referred to as Multi-Level Cell (MLC) FLASH. FLASH memory 122 may be any type of FLASH memory, including NOR FLASH memory, NAND single level cell (SLC) memory, or NAND multi-level cell (MLC) memory.

System memory 120 also includes phase change memory (PCM) 124. Phase change memories are memories that store information based on modifiable material properties, such as whether a material is in a crystalline or amorphous state (phase). For example, in some embodiments, phase change memories include alloys of elements of group VI of the periodic table, such as Te or Se, that are referred to as chalcogenides or chalcogenic materials. Chalcogenides may be used advantageously in phase change memory cells to provide data retention and remain stable even after the power is removed from the nonvolatile memory. Taking the phase change material as Ge₂Sb₂Te₅ for example, two phases or more are exhibited having distinct electrical characteristics useful for memory storage. Phase change memory may be referred to as a Phase Change Memory (PCM), Phase-Change Random Access Memory (PRAM or PCRAM), Ovonic Unified Memory (OUM), Chalcogenide Random Access Memory (C-RAM), or other suitable names.

In part because of the block erase characteristics of FLASH memory, a FLASH translation layer (FTL) 126 may be used to map logical addresses into FLASH memory physical addresses. The FTL may include software as well as translation tables. For example, the FTL may include software that handles read or write requests, and one or more translation tables to map logical addresses to physical addresses in the FLASH memory.

In some embodiments, the logical addresses include addresses within the memory map of processor 110, and the physical addresses are the actual addresses of memory locations within FLASH memory 122. In these embodiments, FTL 126 is able to map different physical locations of FLASH memory into the logical addresses in the memory map of processor 110 at different times.

In other embodiments, the logical addresses include sector numbers and the physical addresses include addresses of blocks within the FLASH memory. For example, in some embodiments, FLASH memory is used to emulate a disk drive in a system. When the system requests a read or write to the disk, it provides a logical address in the form of a sector address on the “disk.” The FTL translates the logical address to the physical address, and the read or write operation is performed at the physical address in the FLASH memory.

Various embodiments of the present invention store all or a portion of FTL 126 in PCM 124. For example, in some embodiments, a translation table that translates logical addresses to physical addresses within FLASH memory 122 is maintained in PCM 124. This greatly simplifies FTL management in part because PCM is not constrained by the block erase characteristics of FLASH memory. Further, in some embodiments, software modules that implement FTL method embodiments are stored in PCM, although this is not a limitation of the present invention.

Although the FTL is shown in PCM, this is not a limitation of the present invention. For example, in some embodiments, the FTL is maintained in another type of nonvolatile memory that it not subject to block erase constraints. Examples include Magnetic Random Access Memory (MRAM), and Ferroelectric Random Access Memory (FRAM).

Magnetic Random Access Memory (MRAM) have magnetic storage elements formed from two ferromagnetic plates located at an intersection of a row and column line and selected by a Magnetic Tunnel Junction (MTJ) device. Current imparted to the row line in one direction causes a magnetic field operative on the MRAM cell biasing the MRAM cell toward a binary state. Due to a magnetic tunnel effect, the electrical resistance of the memory cell changes based on the orientation of the fields in the two plates.

Ferro-electric Random Access Memory (FRAM) have memory cells that may include one transistor and one capacitor. The capacitor includes ferroelectric material and a bi-stable atom in the ferroelectric material is shifted to form two stable polarization states. Memory cell data may be written by positively or negatively orienting the dipoles of the ferroelectric material via an applied polarizing voltage. Data may be read by detecting the voltage of the bit line (BL) connected with the memory cell. Current feed circuits supply electric currents to the bit lines for a predetermined period from a start of a read operation, and read control circuitry senses the direction of the electric polarization as either a high or a low logic state. Each orientation is stable and remains in place even after the electric field is removed, preserving the data within the memory without periodic refresh.

In some embodiments, a bad block table (BBT) may also be stored in PCM. For example, a table that lists bad blocks within FLASH memory 122 may be stored as BBT 128 in PCM 124. This greatly simplifies the management and administration of the BBT in part because PCM is not constrained by the block erase characteristics of FLASH memory.

Memory devices within system memory 120 may be packaged in any manner. For example, in some embodiments, FLASH memory 122 and PCM 124 may be combined in a stacking process to reduce the footprint on a board, packaged separately, or placed in a multi-chip package with the memory component placed on top of the processor.

Solid state disk (SSD) 140 includes FLASH memory 142, PCM 144, and controller 150. Controller 150 may be any type of controller, including a microcontroller, a microprocessor, or the like. SSD 140 emulates the operation of a hard disk. For example, in some embodiments, SSD 140 may appear to the rest of the system as a FAT (file allocation table) formatted hard drive.

In operation, SSD 140 receives read and/or write requests. The read requests are satisfied by reading contents from FLASH memory 142, and the write requests are satisfied by writing to FLASH memory 142. As described above with reference to system memory 120, a FLASH translation layer (FTL) maps logical addresses in the read and write requests to physical addresses in FLASH memory 142. In some embodiments, the logical addresses include sector numbers and the physical addresses include blocks within the FLASH memory. The FTL translates the logical address to the physical address, and the read or write operation is performed at the physical address in the FLASH memory.

Various embodiments of the present invention store all or a portion of FTL 146 in PCM 144. For example, in some embodiments, a translation table that translates logical addresses to physical addresses within FLASH memory 142 is maintained in PCM 144. This greatly simplifies FTL management in part because PCM is not constrained by the block erase characteristics of FLASH memory. Further, in some embodiments, software modules that implement FTL method embodiments are stored in PCM, although this is not a limitation of the present invention.

In some embodiments, a bad block table (BBT) may also be stored in PCM. For example, a table that lists bad blocks within FLASH memory 142 may be stored as BBT 148 in PCM 144. This greatly simplifies the management and administration of the BBT in part because PCM is not constrained by the block erase characteristics of FLASH memory.

Although the FTL and BBT are shown in PCM, this is not a limitation of the present invention. For example, in some embodiments, the FTL and/or BBT are maintained in another type of nonvolatile memory that it not subject to block erase constraints. Examples include Magnetic Random Access Memory (MRAM), and Ferroelectric Random Access Memory (FRAM).

Nonvolatile memory devices with translation tables may be present anywhere in system 100. For example, in some embodiments, one or more of the cores within processor 100 may include FLASH memory and PCM, where translation tables are maintained in PCM. In these embodiments, FTL operations may be provided by the core that includes the nonvolatile memory.

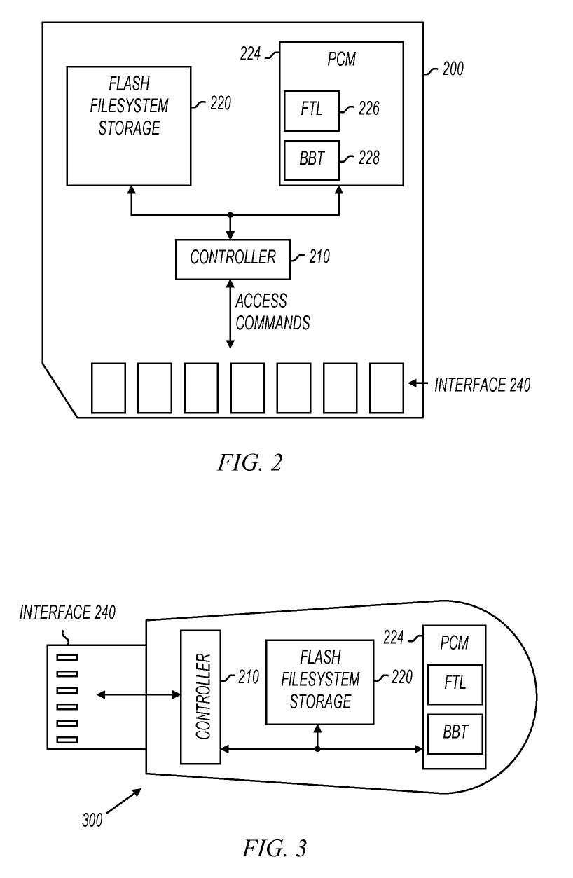

FIG. 2 shows a memory system in accordance with various embodiments of the present invention. Memory system 200 includes FLASH memory 220, PCM 224, controller 210, and interface 240. Memory system 200 is shown having a Secure Digital (SD) form factor, although this is not a limitation of the present invention. For example, in some embodiments, memory system 200 may be a card compatible with a bus within a personal computer. Also for example, in some embodiments, memory system 200 may be a micro-SD card, a memory stick, a MultiMediaCard (MMC), embedded MMC (eMMC), or any other type of card.

In operation, controller 210 receives access commands from interface 240. The access commands may take any form. For example, if memory system 200 operates as a solid state disk, the access commands may be disk access commands. In other embodiments, the access commands may be other than disk access commands. The access commands include logical addresses, and FLASH memory 220 is addressed using physical addresses. Controller 210 maps logical addresses received in the access commands to physical addresses in the FLASH memory.

FLASH memory 220 is used for data storage. In some embodiments, FLASH memory 220 includes a file system that provides storage for a solid state disk, and PCM 224 includes FTL 226 and BBT 228. As described above with reference to previous figures, FTL 226 includes at least a translation table that maps logical to physical addresses. In some embodiments, FTL 226 also includes software components executable by controller 210 to perform address translations and other FLASH translation layer tasks.

The various components shown in FIG. 2 may be packaged in any manner. For example, in some embodiments, controller 210 and FLASH memory 220 are fabricated on the same semiconductor substrate. Further, in some embodiments, PCM 224 is fabricated on a common substrate with FLASH memory 220 and controller 210. Further in some embodiments, controller 210 and FLASH memory 220 are fabricated on one substrate and PCM 224 is fabricated on a second substrate. In some embodiments, the two substrates are stacked prior to packaging in memory system 200.

FIG. 3 shows a memory system in accordance with various embodiments of the present invention. Memory system 300 includes FLASH memory 220, PCM 224, controller 210, and interface 240, all of which are described above with reference to FIG. 2. Memory system 300 is shown having a universal serial bus (USB) device form factor, although this is not a limitation of the present invention. Memory system 300 may take any form factor without departing from the scope of the present invention.

Memory systems 200 (FIG. 2) and 300 (FIG. 3) are but examples of apparatuses that include FLASH memory and non-FLASH memory with translation tables. The apparatuses according to embodiments of the invention are not limited to memory cards or USB devices, but instead may take any form. They may be embedded in devices such as cameras, phones, media players, GPS devices, or any other type of device. They may also take on any stand-alone form factor, including memory cards and USB devices.

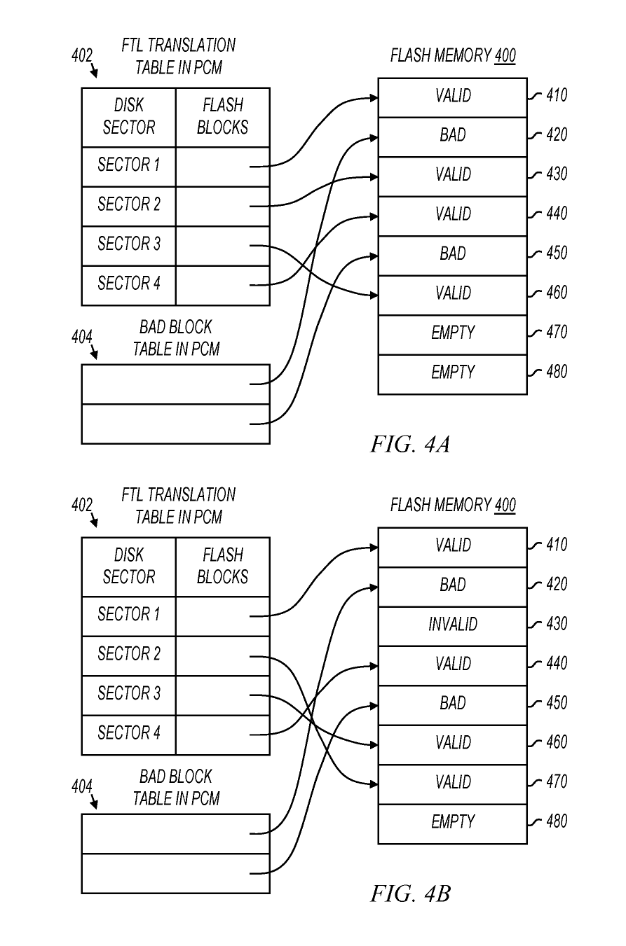

FIGS. 4A and 4B show FLASH translation layer (FTL) translation tables and FLASH bad block tables (BBT) maintained in phase change memory (PCM). Referring now to FIG. 4A, translation table 402 includes logical address entries and physical address entries. The logical address entries are shown as disk sectors, although this is not a limitation of the present invention. The logical address entries may represent any addressing scheme. The physical entries are shows as FLASH memory blocks, although this is not a limitation of the present invention. Physical addresses in the translation table may be at any level of granularity, including blocks.

The term “block” as used herein refers to a finite amount of storage within a FLASH memory device. A block may be any size, from a single bit to something less than the entire device. In some embodiments, a block corresponds to a section of the FLASH memory device that is erased as a unit, but this is not a limitation of the present invention. For example, an erase operation in a FLASH memory may erase one block, less than one block, or more than one block.

FLASH memory 400 is shown having eight blocks. In practice, a FLASH memory device may have many more blocks. Eight blocks are shown for simplicity. Similarly, translation table 402 is shown with only four entries. In practice, a translation table may have many more entries. Four translation table entries are shown for simplicity. The same is true for bad block table 404. In practice, the bad block table will be much larger than shown in FIG. 4A.

The eight blocks shown in FLASH memory 400 include blocks 410, 420, 430, 440, 450, 460, 470, and 480. Blocks 410, 430, 440, and 460 are valid and have corresponding translation table entries. For example, sector 1 data is stored in block 410, sector 2 data is stored in block 430, sector 3 data is stored in block 460, and sector 4 data is stored in block 440. Blocks 420 and 450 are bad, and are pointed to by bad block table 404.

If a read request is received, the FTL will reference translation table 402 in PCM and determine where the corresponding data is stored within the FLASH memory. For example, if a read request specifies a logical address corresponding to sector 2, the FTL will determine that sector 2 data is stored in block 430.

FIG. 4B shows the state of the translation table and the FLASH memory after a write to sector 2 has occurred. In the example of FIG. 4B, a write request that specifies sector 2 has been processed. The FTL has stored the new sector 2 data in empty block 470 (shown as empty in FIG. 4A and valid in FIG. 4B). Further, the translation table 402 in PCM has been updated so that sector 2 now points to block 470. Block 430 has been marked as invalid, and will go unused until erased.

The translation table 402 is shown residing in PCM. This provides nonvolatile storage for the translation table without the necessity of moving the table within FLASH memory because of the block erase characteristics. In some embodiments, more of the FTL is stored in PCM. For example, software modules that maintain the translation tables may be stored in PCM. These additional FTL components are not shown in FIGS. 4A and 4B for simplicity.

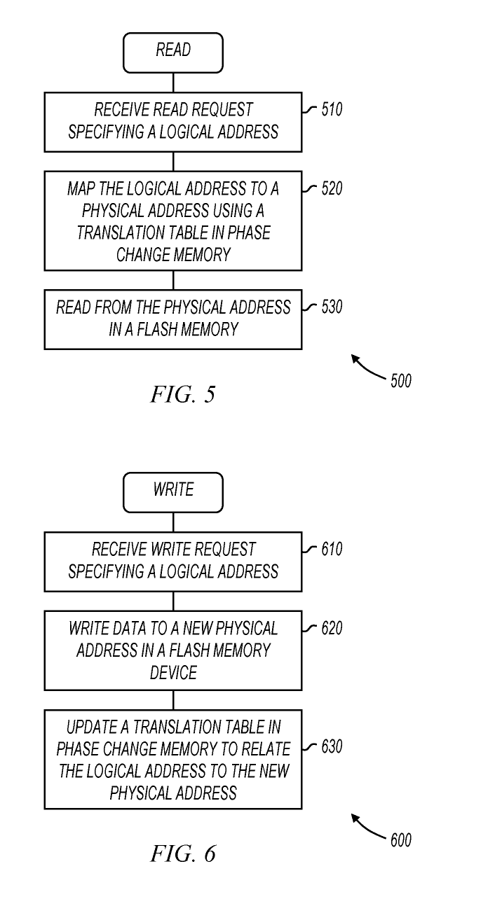

FIG. 5 shows a flow diagram in accordance with various embodiments of the invention. In some embodiments, method 500, or portions thereof, is performed by a processor or controller coupled to or within a memory device or system. For example, method 500 may be performed by processor 110 (FIG. 1), controller 150 (FIG. 1), or controller 210 (FIGS. 2, 3). The various actions in method 500 may be performed in the order presented, or may be performed in a different order. Further, in some embodiments, some actions listed in FIG. 5 are omitted from method 500.

Method 500 is shown beginning at block 510 in which a read request is received. The read request specifies a logical address. For example, in solid state disk embodiments, the read request may specify a disk sector. In other embodiments, the logical address may correspond to an address other than a disk sector. At 520, the logical address is mapped to a physical address using a translation table in phase change memory (PCM). For example, referring back to FIG. 4A, translation table 402 may be used to map a sector to a block within a FLASH memory device. At 530, the physical address in the FLASH memory is read.

FIG. 6 shows a flow diagram in accordance with various embodiments of the invention. In some embodiments, method 600, or portions thereof, is performed by a processor or controller coupled to or within a memory device or system. For example, method 600 may be performed by processor 110 (FIG. 1), controller 150 (FIG. 1), or controller 210 (FIGS. 2, 3). The various actions in method 600 may be performed in the order presented, or may be performed in a different order. Further, in some embodiments, some actions listed in FIG. 6 are omitted from method 600.

Method 600 is shown beginning at block 610 in which a write request is received. The write request specifies a logical address. For example, in solid state disk embodiments, the write request may specify a disk sector. In other embodiments, the logical address may correspond to an address other than a disk sector. At 620, data is written to a new physical address in a FLASH memory device. For example, referring back to FIG. 4B, previously empty block 470 in FLASH memory is written to when a write request is received that specifies a logical address of sector 2. At 630 a translation table in phase change memory is updated to relate the logical address to the new physical address. In the example of FIG. 4B, this corresponds to updating translation table 402 so that the entry having logical address sector 2 points to block 470 in the FLASH memory.

Although the present invention has been described in conjunction with certain embodiments, it is to be understood that modifications and variations may be resorted to without departing from the scope of the invention as those skilled in the art readily understand. Such modifications and variations are considered to be within the scope of the invention and the appended claims.

What is claimed is:

1. An apparatus comprising:
a FLASH memory device addressable by physical addresses; and
a phase change memory (PCM) device having a translation table that maps logical addresses to the physical addresses in the FLASH memory device.

2. The device of claim 1 further comprising a controller to modify the translation table when performing write operations to the FLASH memory device.

3. The device of claim 2 wherein the controller implements a FLASH translation layer (FTL) to map a disk file system to a solid state file system.

4. The device of claim 3 wherein the disk file system comprises a file allocation table (FAT) file system.

5. The device of claim 2 wherein the logical addresses include sector and the physical addresses include blocks.

6. The device of claim 1 wherein the PCM device includes a bad block table (BBT) that identifies bad blocks in the FLASH memory device.

7. The device of claim 1 wherein the device comprises a solid state disk.

8. The device of claim 1 wherein the device comprises a memory card.

9. The device of claim 1 wherein the device comprises a universal serial bus (USB) drive.

10. A method comprising:
receiving a write request having a logical address;
writing to a physical address in a FLASH memory device; and
modifying a translation table in a phase change memory (PCM) device to relate the logical address and the physical address.

11. The method of claim 10 wherein receiving a write request comprises receiving a request to write to a disk.

12. The method of claim 11 wherein the logical address comprises a disk sector.

13. The method of claim 10 wherein the translation table is part of a FLASH translation layer (FTL) to map a file allocation table (FAT) file system to a solid state file system.

14. The method of claim 10 wherein the method is performed by a controller packaged together with the FLASH memory device and the PCM device.

15. A computer-readable medium having instructions stored thereon that when accessed result in a memory system performing:
receiving a read request that specifies a logical address;
mapping the logical address to a physical address using a translation table stored in phase change memory (PCM); and
reading from the physical address in a FLASH memory device.

16. The computer-readable medium of claim 15 wherein the logical address specifies a disk sector.

17. The computer-readable medium of claim 15 wherein the instructions when accessed further result in the memory system receiving a write request that specifies the logical address.

18. The computer-readable medium of claim 17 wherein the instructions when accessed further result in the memory system writing to a new physical address in the FLASH memory device.

19. The computer-readable medium of claim 18 wherein the instructions when accessed further result in the memory system updating the translation table in PCM to map the logical address to the new physical address.
